(19) United States
(12) Patent Application Publication
(10) Pub. No.: US 2025/0149300 A1
(43) Pub. Date: May 8, 2025

(54) PLASMA PROCESSING APPARATUS AND PLASMA PROCESSING METHOD

(71) Applicant: Tokyo Electron Limited, Tokyo (JP)

(72) Inventors: Tangkuei WANG, Miyagi (JP); Tetsuya OHISHI, Miyagi (JP); Masafumi URAKAWA, Miyagi (JP); Shinya MORIKITA, Miyagi (JP)

(73) Assignee: Tokyo Electron Limited, Tokyo (JP)

(21) Appl. No.: 19/015,772

(22) Filed: Jan. 10, 2025

Related U.S. Application Data
(63) Continuation of application No. PCT/JP2023/025154, filed on Jul. 6, 2023.

(30) Foreign Application Priority Data
Jul. 15, 2022 (JP) 2022-113747

(51) Int. Cl. H01J 37/32

(52) U.S. Cl. CPC H01J 37/32174; H01J 37/32146; H01J 2237/3346

(57) ABSTRACT

In a plasma processing apparatus disclosed, a controller performs repetition of a cycle. The cycle includes supplying a pulse of a source high-frequency power from a high-frequency power supply for generating plasma from gas in a chamber, and supplying a pulse of an electric bias to a substrate support from a bias power supply. The pulse of the electric bias includes a direct current voltage pulse periodically generated at a bias frequency of 1 MHz or less. A repetition frequency of the cycle is 5 kHz or more. A start timing of the pulse of the electric bias is simultaneous with or earlier than a stop timing of the pulse of the source high-frequency power. A stop timing of the pulse of the electric bias is later than the stop timing of the pulse of the source high-frequency power.

### CROSS-REFERENCE TO RELATED APPLICATIONS

This application is a bypass continuation application of International Application No. PCT/JP2023/025154 having an international filing date of Jul. 6, 2023 and designating the United States, the international application being based upon and claiming the benefit of priority from Japanese Patent Application No. 2022-113747, filed on Jul. 15, 2022, the entire contents of each are incorporated herein by reference.

### TECHNICAL FIELD

An exemplary embodiment of the present disclosure relates to a plasma processing apparatus and a plasma processing method.

### BACKGROUND

A plasma processing apparatus has been used to etch a film of a substrate. The plasma processing apparatus includes a chamber, a substrate support, a source high-frequency power supply, and a bias high-frequency power supply. The substrate support is provided in the chamber. The source high-frequency power supply supplies source high-frequency power in order to generate plasma from gas in the chamber. The bias high-frequency power supply supplies bias high-frequency power to the substrate support in order to draw ions from the plasma to a substrate on the substrate support. Such a plasma processing apparatus is disclosed in Patent Document 1 below.

### PRIOR ART DOCUMENTS

### Patent Documents

Patent Document 1: Japanese Patent Laid-open Publication No. 2000-173993

According to one embodiment of the present disclosure, a plasma processing apparatus is provided. The plasma processing apparatus includes a chamber, a substrate support, a high-frequency power supply, a bias power supply, and a controller. The substrate support is provided in the chamber. The high-frequency power supply is configured to supply source high-frequency power for generating plasma in the chamber. The bias power supply is electrically coupled to the substrate support. The controller is configured to control the high-frequency power supply and the bias power supply. The controller performs repetition of a cycle. The cycle includes: (i) supplying a pulse of the source high-frequency power from the high-frequency power supply in order to generate the plasma from gas in the chamber; and (ii) supplying a pulse of an electric bias to the substrate support from the bias power supply. The pulse of the electric bias includes a direct current (DC) voltage pulse periodically generated at a bias frequency of 1 MHz or less. A pulse frequency, which is a repetition frequency of the cycle, is 5 kHz or more. The controller sets, within the cycle, a start timing of the pulse of the electric bias in (ii) to be later than a start timing of the pulse of the source high-frequency power in (i) and to be simultaneous with or earlier than a stop timing of the pulse of the source high-frequency power in (i). The controller sets a stop timing of the pulse of the electric bias in (ii) to be later than the stop timing of the pulse of the source high-frequency power.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram for explaining a configuration example of a plasma processing system.

FIG. 2 is a diagram for explaining a configuration example of a capacitively coupled plasma processing apparatus.

FIG. 3 is a flowchart of a plasma processing method according to one exemplary embodiment.

FIG. 4 is a diagram illustrating a detailed example of step STc of the plasma processing method illustrated in FIG. 3.

FIGS. 5A to 5D are partially enlarged cross-sectional views of an exemplary substrate related to each process of the plasma processing method illustrated in FIG. 3.

FIG. 6 is a timing chart related to a plasma processing method according to one exemplary embodiment.

FIGS. 7A and 7B are timing charts related to a plasma processing method according to one exemplary embodiment.

FIG. 8 is a timing chart related to a plasma processing method according to one exemplary embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, various exemplary embodiments will be described in detail with reference to the accompanying drawings. Like reference numerals will be given to like or corresponding parts throughout the drawings.

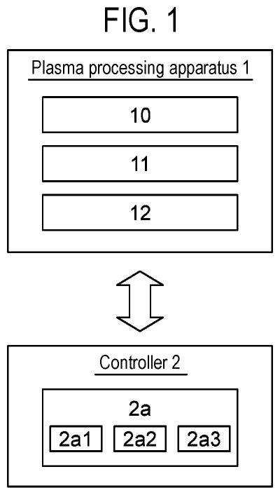

FIG. 1 is a diagram for explaining a configuration example of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 also has at least one gas supply port for supplying at least one process gas into the plasma processing space and at least one gas exhaust port for exhausting gas from the plasma processing space. The gas supply port is connected to a gas supplier 20 described later, and the gas exhaust port is connected to an exhaust system 40 described later. The substrate support 11 is disposed in the plasma processing space and has a substrate support surface for supporting a substrate.

The plasma generator 12 is configured to generate plasma from the at least one process gas supplied into the plasma processing space. The plasma formed in the plasma processing space may be capacitively coupled plasma (CCP), inductively coupled plasma (ICP), electron cyclotron resonance (ECR) plasma, helicon wave plasma (HWP), or surface wave plasma (SWP).

The controller 2 processes computer-executable instructions that cause various processes described in this disclosure to be executed by the plasma processing apparatus 1. The controller 2 may be configured to control each element of the plasma processing apparatus 1 to execute various processes described herein. In one embodiment, a part or all of the controller 2 may be included in the plasma processing apparatus 1. The controller 2 may include a processor 2a1, a storage 2a2, and a communication interface 2a3. The controller 2 is realized, for example, by a computer 2a. The processor 2al may be configured to perform various control operations by reading a program from the storage 2a2 and executing the read program. This program may be stored in the storage 2a2 in advance or may be acquired via a medium when necessary. The acquired program is stored in the storage 2a2 and is read from the storage 2a2 by the processor 2a1 and executed. The medium may be various non-transitory storage media readable by the computer 2a or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

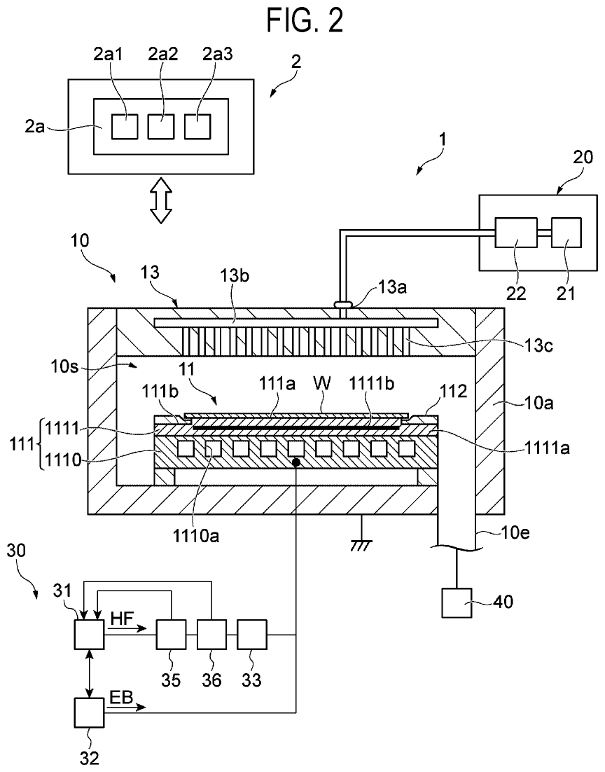

Hereinafter, a configuration example of a capacitively coupled plasma processing apparatus (hereinafter “CCP processing apparatus”) as an example of the plasma processing apparatus 1 will be described. FIG. 2 is a diagram for explaining a configuration example of the CCP processing apparatus.

The CCP processing apparatus 1 includes the plasma processing chamber 10, the gas supplier 20, a power supply system 30, and the exhaust system 40. The plasma processing apparatus 1 also includes the substrate support 11 and a gas introduction portion. The gas introduction portion is configured to introduce at least one process gas into the plasma processing chamber 10. The gas introduction portion includes a shower head 13. The substrate support 11 is disposed in the plasma processing chamber 10. The shower head 13 is disposed above the substrate support 11. In one embodiment, the shower head 13 constitutes at least a part of the ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The substrate support 11 is electrically insulated from the housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 when viewed in a plan view. The substrate W is disposed on the central region 111a of the main body 111, and the ring assembly 112 is disposed on the annular region 111b of the main body 111 so as to surround the substrate W on the central region 111a of the main body 111. Therefore, the central region 111a is also called a substrate support surface for supporting the substrate W, and the annular region 111b is also called a ring support surface for supporting the ring assembly 112.

In one embodiment, the main body 111 includes a base 1110 and an electrostatic chuck 1111. The base 1110 includes a conductive member. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Another member surrounding the electrostatic chuck 1111, such as an annular electrostatic chuck or an annular insulating member, may have the annular region 111b. In this case, the ring assembly 112 may be disposed on the annular electrostatic chuck or the annular insulating member or may be disposed on both the electrostatic chuck 1111 and the annular insulating member.

The ring assembly 112 includes one or plural annular members. In one embodiment, the one or plural annular members include one or plural edge rings and at least one cover ring. The edge ring is formed of a conductive material or an insulating material, and the cover ring is formed of an insulating material.

The substrate support 11 may include a temperature adjustment module configured to adjust at least one of the electrostatic chuck 1111, the ring assembly 112, or the substrate to a target temperature. The temperature adjustment module may include a heater, a heat transfer medium, a flow passage 1110a, or a combination thereof. A heat transfer fluid such as brine or gas flows through the flow passage 1110a. In one embodiment, the flow passage 1110a is formed in the base 1110, and one or plural heaters are disposed in the ceramic member 1111a of the electrostatic chuck 1111. The substrate support 11 may include a heat transfer gas supplier configured to supply a heat transfer gas to a gap between a back surface of the substrate W and the central region 111a.

The shower head 13 is configured to introduce at least one process gas from the gas supplier 20 into the plasma processing space 10s. The shower head 13 has at least one gas supply port 13a, at least one gas diffusion chamber 13b, and a plurality of gas introduction ports 13c. The process gas supplied to the gas supply port 13a passes through the gas diffusion chamber 13b and is introduced into the plasma processing space 10s from the gas introduction ports 13c. The shower head 13 also includes at least one upper electrode. In addition to the shower head 13, the gas introduction portion may include one or plural side gas injectors (SGIs) installed in one or plural openings formed in the sidewall 10a.

The gas supplier 20 may include at least one gas source 21 and at least one flow rate controller 22. In one embodiment, the gas supplier 20 is configured to supply at least one process gas to the shower head 13 from each corresponding gas source 21 through each corresponding flow controller 22. Each flow controller 22 may include, for example, a mass flow controller or a pressure-controlled flow rate controller. In addition, the gas supplier 20 may include at least one flow rate modulation device that modulates or pulses the flow rate of the at least one process gas.

The exhaust system 40 may be connected to, for example, a gas exhaust port 10e provided in the bottom of the plasma processing chamber 10. The exhaust system 40 may include a pressure regulating valve and a vacuum pump. Pressure in the plasma processing space 10s is regulated by the pressure regulating valve. The vacuum pump may include a turbomolecular pump, a dry pump, or a combination thereof.

The power supply system 30 includes a high-frequency power supply 31 and a bias power supply 32. The high-frequency power supply 31 constitutes the plasma generator 12 of one embodiment. The high-frequency power supply 31 is configured to generate source high-frequency power HF. The source high-frequency power HF has a source frequency. That is, the source high-frequency power HF has a sinusoidal waveform, a frequency of which is a source frequency. The source frequency may be a frequency within a range of 10 MHz to 150 MHz. The high-frequency power supply 31 is electrically connected to a high-frequency electrode through a matcher 33 and is configured to supply the source high-frequency power HF to the high-frequency electrode. The high-frequency electrode may be provided in the substrate support 11. The high-frequency electrode may be at least one electrode provided in the conductive member or the ceramic member 1111a of the base 1110. Alternatively, the high-frequency electrode may be an upper electrode. When the source high-frequency power HF is supplied to the high-frequency electrode, plasma is generated from gas in the chamber 10.

The matcher 33 has a variable impedance. The variable impedance of the matcher 33 is set so as to reduce the reflection of the source high-frequency power HF from a load. The matcher 33 can be controlled by, for example, the controller 2.

The bias power supply 32 is electrically coupled to the substrate support 11. The bias power supply 32 is electrically connected to a bias electrode in the substrate support 11 and is configured to supply an electric bias EB to the bias electrode. The bias electrode may be at least one electrode provided in the conductive member or ceramic member 1111a of the base 1110. The bias electrode may be common to the high-frequency electrode. When the electric bias EB is supplied to the bias electrode, ions from the plasma are drawn to the substrate W.

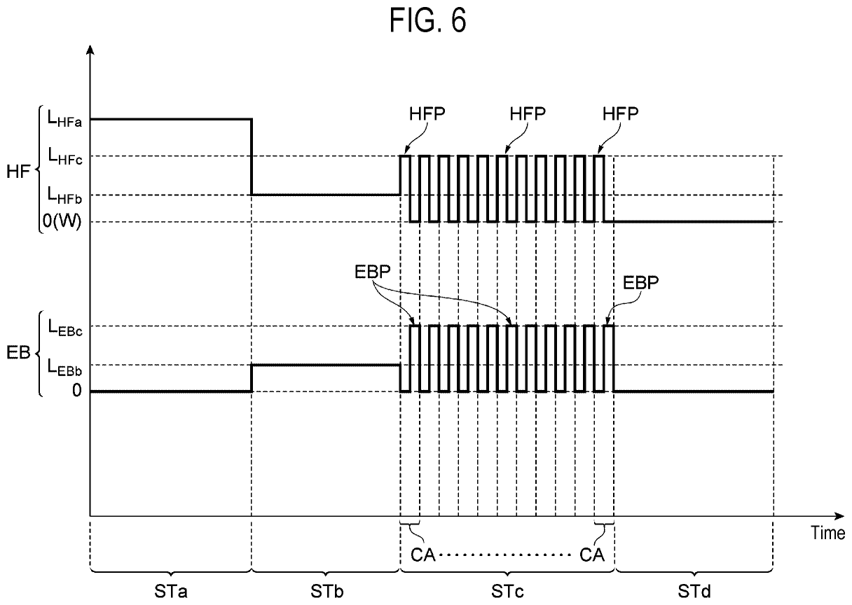

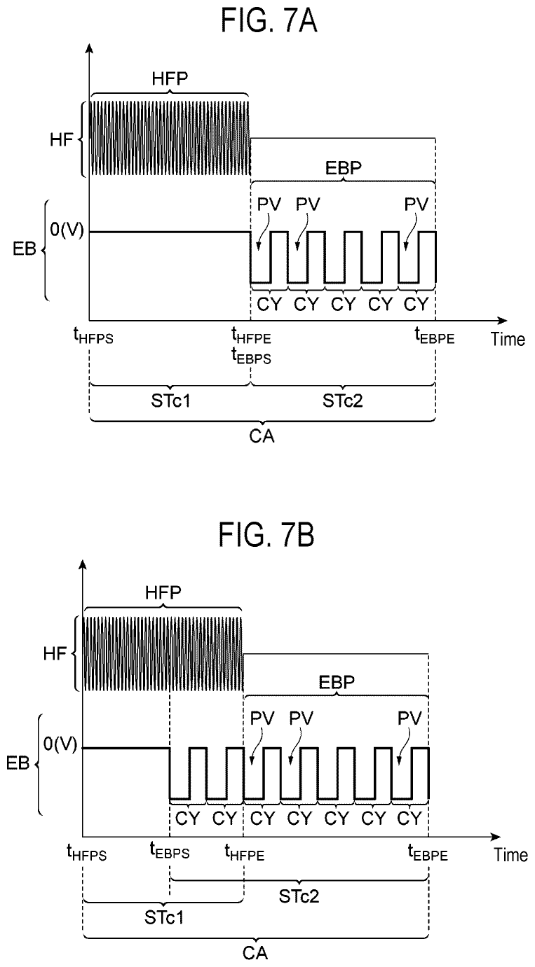

The electric bias EB and an electric bias pulse EBP thereof (see FIG. 6) include a direct current (DC) voltage pulse PV (see FIGS. 7A and 7B) periodically generated at a bias frequency of 1 MHz or less. That is, the electric bias EB and the electric bias pulse EBP are composed of the DC voltage pulse PV periodically generated at a time interval (waveform cycle CY) which is the reciprocal of the bias frequency. The bias frequency may be 400 kHz or less. Hereinafter, the level of the electric bias EB may be described. The level of the electric bias EB is an absolute value of a negative voltage level of the DC voltage pulse PV. In addition, the level of the electric bias EB being zero means that the supply of the electric bias EB to the bias electrode is stopped.

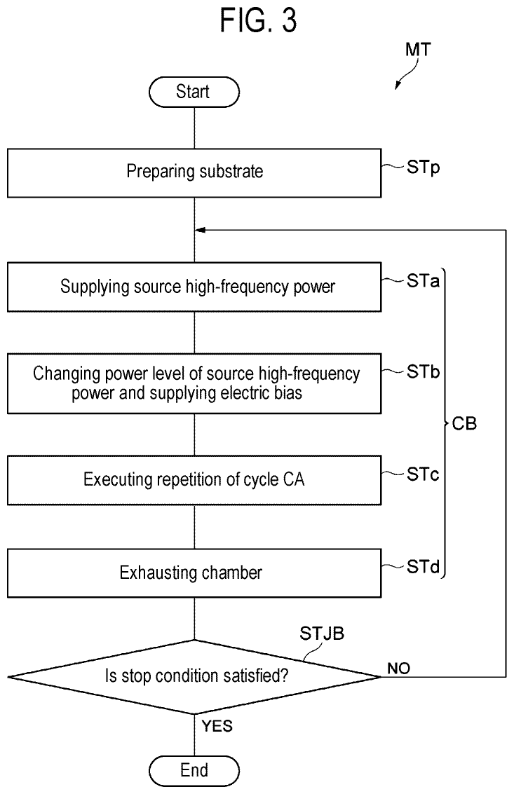

Hereinafter, a plasma processing method according to one exemplary embodiment will be described with reference to FIGS. 3 to 7B together with FIGS. 1 and 2. In addition, the control of each part of the plasma processing apparatus 1 by the controller 2 will also be described. Timing charts of the source high-frequency power HF and the electric bias EB are illustrated in FIG. 6, and FIGS. 7A and 7B.

The plasma processing method illustrated in FIG. 3 (referred to hereinafter as a “method MT”) can be performed using the plasma processing apparatus 1. The method MT includes step STc. The method MT may further include steps STp, STa, and STb. The method MT may further include step STd. Steps STa, STb, STc, and STd can be performed by control of each part of the plasma processing apparatus 1 by the controller 2.

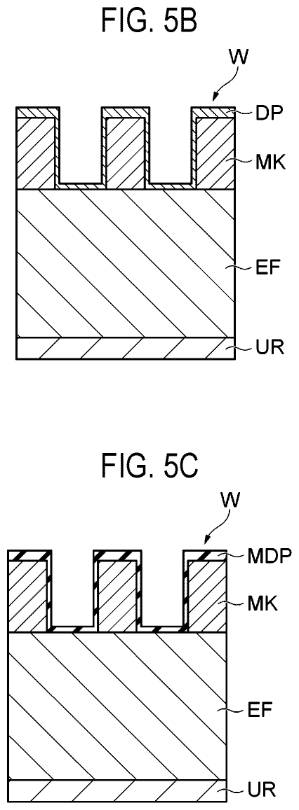

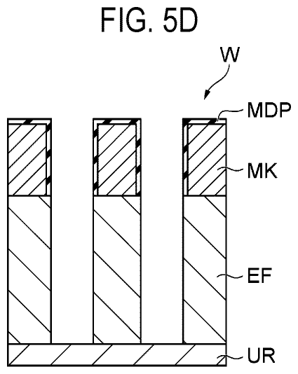

In step STp, the substrate W is prepared on the substrate support 11 in the chamber 10. The substrate W is placed on the substrate support 11 and held by the electrostatic chuck 1111. As illustrated in FIG. 5A, the substrate W includes a film (etch film) EF and a mask MK. The film EF is a dielectric film. The film EF is made of, for example, silicon oxide. The mask MK is provided on the film EF. The mask MK is made of a material selected such that the film EF is selectively etched with respect to the mask MK in step STc. The mask MK is made of, for example, an organic material. The substrate W may further include an underlying region UR. The film EF is provided on the underlaying region UR.

In step STa, as illustrated in FIG. 5B, a deposit DP is formed on the substrate W on the substrate support 11. Therefore, in step STa, a process gas is supplied into the chamber 10, and the source high-frequency power HF is supplied to the high-frequency electrode while the supply of the electric bias EB to the bias electrode is stopped.

The process gas used in step STa has a deposition property. The process gas used in step STa may contain a gas component containing fluorine and carbon. This gas component may be a fluorocarbon gas such as C₄F₈ gas. This gas component may contain a hydrofluorocarbon gas in addition to or instead of the fluorocarbon gas. The process gas may further contain one or more of nitrogen gas, an oxygen-containing gas (e.g., oxygen gas), and a noble gas (e.g., Ar gas).

In step STa, the controller 2 controls the gas supplier 20 to supply the process gas into the chamber 10. In step STa, the controller 2 controls the exhaust system 40 to adjust the pressure in the chamber 10 to a designated pressure. In step STa, the controller 2 controls the bias power supply 32 to stop the supply of the electric bias EB to the bias electrode and controls the high-frequency power supply 31 to supply the source high-frequency power HF to the high-frequency electrode. As illustrated in FIG. 6, the controller 2 sets a power level of the source high-frequency power HF in step STa to a power level L_{HFa}.

As illustrated in FIGS. 3 and 6, step STb is performed after step STa. In step STb, ions from the plasma generated from the process gas in the chamber 10 are supplied to the deposit DP, so that a modified deposit MDP, which is modified from the deposit DP, is formed as illustrated in FIG. 5C. For this reason, in step STb, the source high-frequency power HF is supplied to the high-frequency electrode, and the electric bias EB is supplied to the bias electrode. A power level of the source high-frequency power HF in step STb is changed from the power level L_{HFa} of the source high-frequency power HF in step STa to a power level L_{HFb} as illustrated in FIG. 6. The power level L_{HFb} may be lower than the power level L_{HFa}.

The process gas used to generate the plasma in step STb may be the same as the process gas used in step STa. In step STb, the controller 2 controls the gas supplier 20 to supply the process gas into the chamber 10. In step STb, the controller 2 controls the exhaust system 40 to adjust the pressure in the chamber 10 to a predetermined pressure. In step STb, the controller 2 controls the bias power supply 32 to supply the electric bias EB to the bias electrode. In step STb, the controller 2 controls the high-frequency power supply 31 to supply the source high-frequency power HF to the high-frequency electrode. As illustrated in FIG. 6, the controller 2 sets the power level of the source high-frequency power HF in step STb to the power level L_{HFb}. The controller 2 sets the level of the electric bias EB in step STb to a level L_{EBb}.

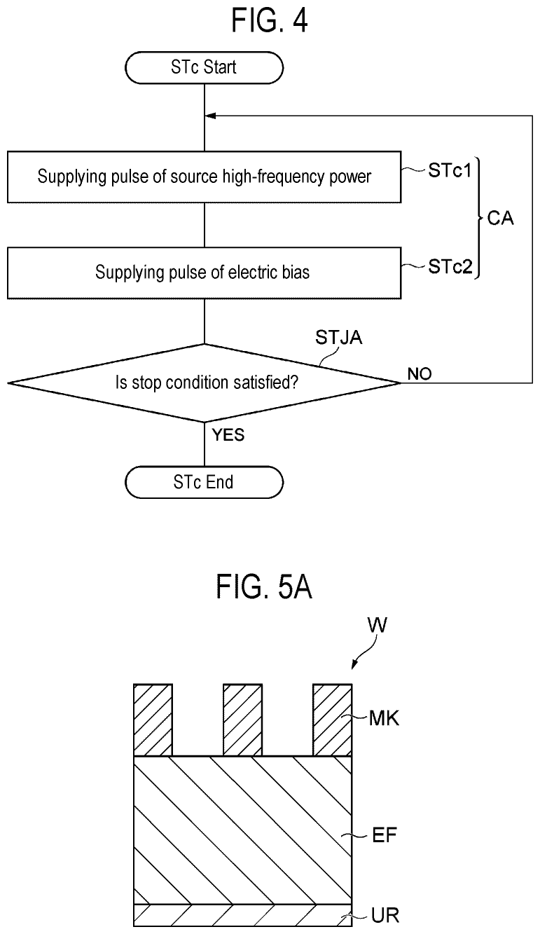

As illustrated in FIGS. 3 and 6, step STc is performed after step STb. In step STc, a cycle CA is repeated for etching the film EF. As illustrated in FIG. 4, the cycle CA includes step STc1 and step STc2.

In step STc1, the source high-frequency power HF is supplied from the high-frequency power supply 31 to the high-frequency electrode in order to generate the plasma from an etching gas in the chamber 10. The etching gas may be the same process gas as the process gas used in step STa and/or step STb. Alternatively, the etching gas may be another gas selected to selectively etch the film EF. As illustrated in FIG. 6, the power level of a pulse HFP of the source high-frequency power HF in step STc1 is set to a power level L_{HFc}. The power level L_{HFc} may be smaller than the power level L_{HFa} and may be larger than the power level L_{HFb}.

In step STc2, a pulse of the electric bias EB is supplied from the bias power supply 32 to the bias electrode in order to draw ions from the plasma generated from the etching gas to the substrate W. As illustrated in FIG. 6, the level of the pulse EBP of the electric bias EB in step STc2 is set to a level L_{EBc}. The level L_{EBc} may be greater than the level L_{EBb}. That is, an absolute value of a negative voltage level of the DC voltage pulse PV in step STc2 may be greater than an absolute value of a negative voltage level of the DC voltage pulse PV in step STb. The absolute value of the negative voltage level of the DC voltage pulse PV in step STc2 may be 100 V or more or 1,000 V or more.

In step STJA of a subsequent process, it is determined whether or not a stop condition is satisfied. The stop condition is satisfied when the number of times that the cycle CA has been performed reaches a predetermined number. If it is determined in step STJA that the stop condition is not satisfied, the cycle CA is performed again. If it is determined in step STJA that the stop condition is satisfied, step STc ends.

A pulse frequency, which is a repetition frequency of the cycle CA, i.e., the reciprocal of the time length of the cycle CA, is 5 kHz or more. The pulse frequency may be 10 kHz or more or 20 kHz or more.

In steps STc1 and STc2, the controller 2 controls the gas supplier 20 to supply the etching gas into the chamber 10. In each of steps STc1 and STc2, the controller 2 controls the exhaust system 40 to adjust the pressure in the chamber 10 to the predetermined pressure. In step STc1, the controller 2 controls the high-frequency power supply 31 to supply the pulse HFP of the source high-frequency power HF to the high-frequency electrode. The controller 2 sets the power level of the pulse HFP in step STc1 to the power level L_{HFc}. The supply of the source high-frequency power HF can be stopped during periods other than a period of step STc1 within the cycle CA. In step STc2, the controller 2 controls the bias power supply 32 to supply the pulse EBP of the electric bias EB to the bias electrode. The controller 2 sets the level of the pulse EBP in step STc2 to the level L_{EBc}. The supply of the electric bias EB can be stopped during periods other than a period of step STc2 within the cycle CA.

As illustrated in FIGS. 7A and 7B, the controller 2 sets a start timing t_{EBPS} of the pulse EBP in step STc2 within the cycle CA to a timing later than a start timing t_{HEPS} of the pulse HFP in step STc1 within the cycle CA. As illustrated in FIG. 7A, the controller 2 sets the start timing t_{EBPS} of the pulse EBP in step STc2 within the cycle CA to a timing identical to a stop timing t_{HFPE} of the pulse HFP in step STc1 within the cycle CA. Alternatively, as illustrated in FIG. 7B, the controller 2 sets the start timing t_{EBPS} of the pulse EBP in step STc2 within the cycle CA to a timing earlier than the stop timing t_{HEPE} of the pulse HFP in step STc1 within the cycle CA. Further, the controller 2 sets a stop timing t_{EBPE} of the pulse EBP in step STc2 within the cycle CA to a timing later than the stop timing t_{HFPE} of the pulse HFP in step STc1 within the cycle CA.

As illustrated in FIGS. 3 and 6, step STd is performed after step STc. In step STd, an etching by-product generated in step STc is exhausted from the chamber 10. In step STd, the controller 2 controls the exhaust system 40 to exhaust the chamber 10. In step STd, the controller 2 controls the high-frequency power supply 31 to stop the supply of the source high-frequency power HF. In step STd, the controller 2 controls the bias power supply 32 to stop the supply of the electric bias EB.

In one embodiment, the method MT may include repetition of a cycle CB including steps STa, STb, and STc as illustrated in FIG. 3. The cycle CB may further include step STd. In this case, in step STJB, it is determined whether or not the stop condition is satisfied. The stop condition is satisfied when the number of times that the cycle CB has been performed reaches a predetermined number. If it is determined in step STJB that the stop condition is not satisfied, the cycle CB is performed again. If it is determined in step STJB that the stop condition is satisfied, the method MT ends.

In the method MT, the film EF is etched by etching in step STc, and a pattern of the mask MK is transferred to the film EF, as illustrated in FIG. 5D.

As described above, the start timing t_{EBPS} of the pulse EBP of the electric bias EB within the cycle CA is simultaneous with or earlier than the stop timing t_{HFPE} of the pulse HFP of the source high-frequency power HF within the cycle CA. The repetition frequency of the cycle CA, i.e., the pulse frequency, is 5 kHz or more. Therefore, the ions of the plasma generated in step STc1 can be supplied to the substrate W in step STc2 without being deactivated. Thus, according to the method MT, the etching rate of the film EF is increased.

In the method MT, the DC voltage pulse PV periodically generated at a bias frequency of 1 MHz or less is used as the pulse EBP of the electric bias EB. Therefore, in step STc2, the dissociation of the etching gas is suppressed by the electric bias EB, and the formation of an excessive deposit on the substrate W is suppressed. In step STc2, monochromatic ions having high energy are supplied to the substrate W. Therefore, a recess having high verticality is formed in the film EF by etching in step STc.

Further, in step STb, ions having relatively high energy are supplied to the deposit DP to extract unnecessary elements (e.g., fluorine) from the deposit DP. Therefore, in the modified deposit MDP obtained in step STb, many bonds with high bond energy (e.g., bonds between carbon and carbon) can be formed. The mask MK is protected from the etching in step STc by the modified deposit MDP. Therefore, according to the method MT, it is possible to suppress the reduction of the mask MK due to etching.

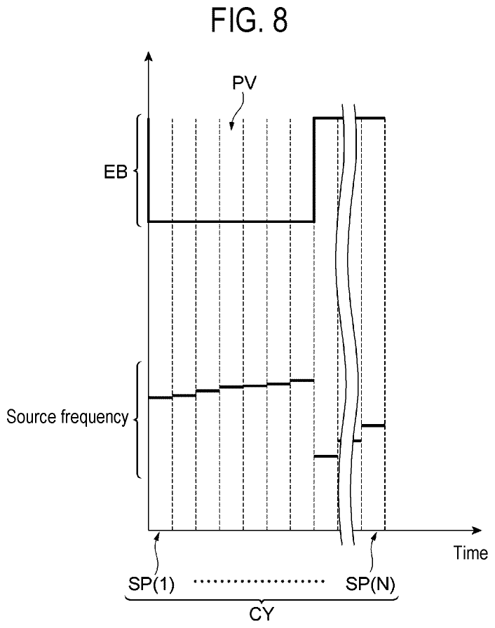

Hereinafter, reference is made to FIG. 8. FIG. 8 illustrates a timing chart of the electric bias EB and the source frequency of the source high-frequency power HF. In a partial period of step STc1 and in step STb, the source high-frequency power HF and the electric bias EB are supplied simultaneously. In an overlap period in which the source high-frequency power HF and the electric bias EB are supplied simultaneously, the source frequency of the source high-frequency power HF may be changed so as to suppress a degree of reflection of the source high-frequency power HF from a load. Specifically, the source frequency may be changed as illustrated in FIG. 8 within a waveform cycle CY of the DC voltage pulse PV within the overlap period.

As illustrated in FIG. 8, the waveform cycle CY may be divided into a plurality of phase periods SP. The source frequency is set so as to reduce the degree of reflection of the source high-frequency power HF in each phase period SP in the waveform cycle CY within the overlap period. The source frequency for each of the phase periods SP in the waveform cycle CY within the overlap period may be set in the high-frequency power supply 31 by the controller 2.

The source frequency for each of the phase periods SP in the waveform cycle CY within the overlap period may be set using a frequency set including a plurality of frequencies prepared in advance for each of the phase periods SP. Alternatively, the source frequency determined to minimize the degree of reflection from the degree of reflection of the source high-frequency power HF obtained using different source frequencies in the same phase period SP (n) in two or more preceding waveform cycles CY may be used in the subsequent phase period SP (n). In addition, the phase period SP (n) represents the n-th phase period among the phase periods SP in the waveform cycle CY.

In order to determine the degree of reflection of the source high-frequency power HF, the plasma processing apparatus 1 may further include a sensor 35 and/or a sensor 36 as illustrated in FIG. 2. The sensor 35 is configured to measure a power level Pr of a reflected wave of the source high-frequency power HF from the load. The sensor 35 includes, for example, a directional coupler. The directional coupler may be provided between the high-frequency power supply 31 and the matcher 33. The sensor 35 may be configured to measure a power level Pf of a traveling wave of the source high-frequency power HF. The controller 2 is notified of the power level Pr of the reflected wave measured by the sensor 35. In addition, the sensor 35 may notify the controller 2 of the power level Pf of the traveling wave.

The sensor 36 includes a voltage sensor and a current sensor. The sensor 36 is configured to measure a voltage V_{RF} and a current I_{RF} in a power supply path connecting the high-frequency power supply 31 and the high-frequency electrode to each other. The source high-frequency power HF is supplied to the high-frequency electrode via this power supply path. The sensor 36 may be provided between the high-frequency power supply 31 and the matcher 33. The controller 2 is notified of the voltage V_{RF} and the current I_{RF}.

The controller 2 generates a representative value from a measured value in each of the phase periods SP. The measured value may be the power level Pr of a reflected wave acquired by the sensor 35. The measured value may be a ratio value (i.e., reflectivity) of the power level Pr of the reflected wave to an output power level of the source high-frequency power HF. The measured value may be a phase difference θ between the voltage V_{RF} and the current I_{RF} acquired by the sensor 36 in each of the phase periods SP. The measured value may be an impedance Z of a load side of the high-frequency power supply 31 in each of the phase periods SP. The impedance Z is determined from the voltage V_{RF} and the current I_{RF} acquired by the sensor 36. The representative value may be an average value or a maximum value of the measured values in each of the phase periods SP. The controller 2 can determine the source frequency using the representative value in each of the phase periods SP as a value representing the degree of reflection of the source high-frequency power HF. The degree of reflection and the source frequency may be determined by the high-frequency power supply 31.

According to one exemplary embodiment of the present disclosure, it is possible to increase an etching rate and the verticality of an opening formed in a substrate.

While various exemplary embodiments have been described above, the present disclosure is not limited to the above-described exemplary embodiments, and various additions, omissions, substitutions, and modifications may be made. In addition, elements in different embodiments can be combined to form other embodiments.

Various exemplary embodiments included in the present disclosure are described in [E1] to [E13] below.

### [E1]

A plasma processing apparatus includes:
a chamber;
a substrate support provided in the chamber;
a high-frequency power supply configured to supply source high-frequency power for generating plasma in the chamber;
a bias power supply electrically coupled to the substrate support; and
a controller configured to control the high-frequency power supply and the bias power supply,
wherein the controller is configured to perform repetition of a cycle including:
(i) supplying a pulse of the source high-frequency power from the high-frequency power supply for generating the plasma from gas in the chamber; and
(ii) supplying a pulse of an electric bias to the substrate support from the bias power supply,
wherein the pulse of the electric bias includes a direct current (DC) voltage pulse periodically generated at a bias frequency of 1 MHz or less,
wherein a pulse frequency, which is a repetition frequency of the cycle, is 5 kHz or more, and
wherein the controller is configured to set, within the cycle,
a start timing of the pulse of the electric bias in (ii) to be later than a start timing of the pulse of the source high-frequency power in (i) and to be simultaneous with or earlier than a stop timing of the pulse of the source high-frequency power in (i), and
a stop timing of the pulse of the electric bias in (ii) to be later than the stop timing of the pulse of the source high-frequency power.

### [E2]

In the plasma processing apparatus of [E1], the controller is configured to perform:
(a) supplying the source high-frequency power from the high-frequency power supply while a process gas having a deposition property is supplied into the chamber and supply of the electric bias is stopped, for forming a deposit on a substrate on the substrate support; and
(b) changing a power level of the source high-frequency power from the power level of the source high-frequency power in (a) and supplying the electric bias, for modifying the deposit by supplying ions from the plasma to the deposit, and
the controller is configured to perform the repetition of the cycle after (a) and (b).

### [E3]

In the plasma processing apparatus of [E2], the controller is configured to perform repetition of another cycle including (a), (b), and the repetition of the cycle including (i) and (ii).

### [E4]

In the plasma processing apparatus of [E3], the controller is configured to perform exhaust of the chamber while the source high-frequency power and the electric bias are stopped, after the cycle including (i) and (ii) in the another cycle.

### [E5]

In the plasma processing apparatus of any one of [E2] to [E4], the controller is configured to set the power level of the source high-frequency power in (b) to a level lower than the power level of the source high-frequency power in (a).

### [E6]

In the plasma processing apparatus of any one of [E2] to [E5], the controller is configured to set an absolute value of a negative voltage level of the DC voltage pulse in (ii) to be greater than the absolute value of the negative voltage level of the DC voltage pulse in (b).

### [E7]

In the plasma processing apparatus of any one of [E1] to [E6], the controller is configured to change a source frequency of the source high-frequency power within a waveform cycle of the DC voltage pulse to suppress a degree of reflection of the source high-frequency power from a load in a period in which supply of the source high-frequency power in (i) and supply of the electric bias are simultaneously performed.

### [E8]

In the plasma processing apparatus of any one of [E1] to [E7], the DC voltage pulse is a negative DC voltage pulse and has an absolute value of 100 V or more in (ii).

### [E9]

In the plasma processing apparatus of any one of [E1] to [E8], the pulse frequency is 10 kHz or more.

### [E10]

In the plasma processing apparatus of any one of [E1] to [E9], the bias frequency is 400 kHz or less.

### [E11]

A plasma processing method includes:
preparing a substrate on a substrate support in a chamber of a plasma processing apparatus, the substrate including a film and a mask provided on the film; and
performing repetition of a cycle for etching the film,
wherein the cycle includes:
(i) supplying a pulse of a source high-frequency power from a high-frequency power supply for generating plasma from gas in the chamber; and
(ii) supplying a pulse of an electric bias to the substrate support from a bias power supply,
wherein the pulse of the electric bias includes a direct current (DC) voltage pulse periodically generated at a bias frequency of 1 MHz or less,
wherein a pulse frequency, which is a repetition frequency of the cycle, is 5 kHz or more, and
wherein, within the cycle,
a start timing of the pulse of the electric bias in (ii) is later than a start timing of the pulse of the source high-frequency power in (i) and is simultaneous with or earlier than a stop timing of the pulse of the source high-frequency power in (i), and
a stop timing of the pulse of the electric bias in (ii) is later than the stop timing of the pulse of the source high-frequency power.

### [E12]

In the plasma processing method of [E11], the plasma processing method further includes:
(a) supplying the source high-frequency power from the high-frequency power supply while a process gas having a deposition property is supplied into the chamber and supply of the electric bias is stopped, for forming a deposit on the substrate on the substrate support; and
(b) changing a power level of the source high-frequency power from the power level of the source high-frequency power in (a) and supplying the electric bias, for modifying the deposit by supplying ions from the plasma to the deposit,
wherein the repetition of the cycle is performed after (a) and (b).

### [E13]

A plasma processing apparatus includes:
a chamber;
a substrate support provided in the chamber;
a high-frequency power supply configured to supply source high-frequency power for generating plasma in the chamber;
a bias power supply electrically coupled to the substrate support; and
a controller configured to control the high-frequency power supply and the bias power supply,
wherein the controller is configured to perform:
(a) supplying the source high-frequency power from the high-frequency power supply while a process gas having a deposition property is supplied into the chamber and supply of the electric bias to the substrate support from the bias power supply is stopped; and
(b) changing a power level of the source high-frequency power from the power level of the source high-frequency power in (a) and supplying the electric bias, and
wherein the controller is configured to perform, after (a) and (b), repetition of a cycle including:
(i) supplying a pulse of the source high-frequency power from the high-frequency power supply; and
(ii) supplying a pulse of the electric bias to the substrate support from the bias power supply, and
wherein the controller is configured to set, within the cycle,
a start timing of the pulse of the electric bias in (ii) to be later than a start timing of the pulse of the source high-frequency power in (i) and to be simultaneous with or earlier than a stop timing of the pulse of the source high-frequency power in (i), and
a stop timing of the pulse of the electric bias in (ii) to be later than the stop timing of the pulse of the source high-frequency power.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus, comprising:
a chamber;
a substrate support provided in the chamber;
a high-frequency power supply configured to supply source high-frequency power for generating plasma in the chamber;
a bias power supply electrically coupled to the substrate support; and
a controller configured to control the high-frequency power supply and the bias power supply,
wherein the controller is configured to perform repetition of a cycle including:
(i) supplying a pulse of the source high-frequency power from the high-frequency power supply for generating the plasma from gas in the chamber; and
(ii) supplying a pulse of an electric bias to the substrate support from the bias power supply,
wherein the pulse of the electric bias includes a direct current voltage pulse periodically generated at a bias frequency of 1 MHz or less,
wherein a pulse frequency, which is a repetition frequency of the cycle, is 5 kHz or more, and
wherein the controller is configured to set, within the cycle,
a start timing of the pulse of the electric bias in (ii) to be later than a start timing of the pulse of the source high-frequency power in (i) and to be simultaneous with or earlier than a stop timing of the pulse of the source high-frequency power in (i), and
a stop timing of the pulse of the electric bias in (ii) to be later than the stop timing of the pulse of the source high-frequency power.

2. The plasma processing apparatus of claim 1, wherein the controller is configured to perform:
(a) supplying the source high-frequency power from the high-frequency power supply while a process gas having a deposition property is supplied into the chamber and supply of the electric bias is stopped, for forming a deposit on a substrate on the substrate support; and
(b) changing a power level of the source high-frequency power from the power level of the source high-frequency power in (a) and supplying the electric bias, for modifying the deposit by supplying ions from the plasma to the deposit, and
wherein the controller is configured to perform the repetition of the cycle after (a) and (b).

3. The plasma processing apparatus of claim 2, wherein the controller is configured to perform repetition of another cycle including (a), (b), and the repetition of the cycle including (i) and (ii).

4. The plasma processing apparatus of claim 3, wherein the controller is configured to perform exhaust of the chamber while the source high-frequency power and the electric bias are stopped, after the cycle including (i) and (ii) in the another cycle.

5. The plasma processing apparatus of claim 4, wherein the controller is configured to set the power level of the source high-frequency power in (b) to a level lower than the power level of the source high-frequency power in (a).

6. The plasma processing apparatus of claim 2, wherein the controller is configured to set an absolute value of a negative voltage level of the direct current voltage pulse in (ii) to be greater than the absolute value of the negative voltage level of the direct current voltage pulse in (b).

7. The plasma processing apparatus of claim 1, wherein the controller is configured to change a source frequency of the source high-frequency power within a waveform cycle of the direct current voltage pulse to suppress a degree of reflection of the source high-frequency power from a load in a period in which supply of the source high-frequency power in (i) and supply of the electric bias are simultaneously performed.

8. The plasma processing apparatus of claim 1, wherein the direct current voltage pulse is a negative direct current voltage pulse and has an absolute value of 100 V or more in (ii).

9. The plasma processing apparatus of claim 1, wherein the pulse frequency is 10 kHz or more.

10. The plasma processing apparatus of claim 1, wherein the bias frequency is 400 kHz or less.

11. The plasma processing apparatus of claim 2, wherein the controller is configured to set the power level of the source high-frequency power in (b) to a level lower than the power level of the source high-frequency power in (a).

12. A plasma processing method, comprising:
preparing a substrate on a substrate support in a chamber of a plasma processing apparatus, the substrate including a film and a mask provided on the film; and
performing repetition of a cycle for etching the film,
wherein the cycle includes:
(i) supplying a pulse of a source high-frequency power from a high-frequency power supply for generating plasma from gas in the chamber; and
(ii) supplying a pulse of an electric bias to the substrate support from a bias power supply,
wherein the pulse of the electric bias includes a direct current voltage pulse periodically generated at a bias frequency of 1 MHz or less,
wherein a pulse frequency, which is a repetition frequency of the cycle, is 5 kHz or more, and
wherein, within the cycle,
a start timing of the pulse of the electric bias in (ii) is later than a start timing of the pulse of the source high-frequency power in (i) and is simultaneous with or earlier than a stop timing of the pulse of the source high-frequency power in (i), and
a stop timing of the pulse of the electric bias in (ii) is later than the stop timing of the pulse of the source high-frequency power.

13. The plasma processing method of claim 12, further comprising:
(a) supplying the source high-frequency power from the high-frequency power supply while a process gas having a deposition property is supplied into the chamber and supply of the electric bias is stopped, for forming a deposit on the substrate on the substrate support; and
(b) changing a power level of the source high-frequency power from the power level of the source high-frequency power in (a) and supplying the electric bias, for modifying the deposit by supplying ions from the plasma to the deposit,
wherein the repetition of the cycle is performed after (a) and (b).

14. A plasma processing apparatus, comprising:
a chamber;
a substrate support provided in the chamber;
a high-frequency power supply configured to supply source high-frequency power for generating plasma in the chamber;
a bias power supply electrically coupled to the substrate support; and
a controller configured to control the high-frequency power supply and the bias power supply,
wherein the controller is configured to perform:
(a) supplying the source high-frequency power from the high-frequency power supply while a process gas having a deposition property is supplied into the chamber and supply of an electric bias to the substrate support from the bias power supply is stopped; and
(b) changing a power level of the source high-frequency power from the power level of the source high-frequency power in (a) and supplying the electric bias, and
wherein the controller is configured to perform, after (a) and (b), repetition of a cycle including:
(i) supplying a pulse of the source high-frequency power from the high-frequency power supply; and
(ii) supplying a pulse of the electric bias to the substrate support from the bias power supply, and
wherein the controller is configured to set, within the cycle,
a start timing of the pulse of the electric bias in (ii) to be later than a start timing of the pulse of the source high-frequency power in (i) and to be simultaneous with or earlier than a stop timing of the pulse of the source high-frequency power in (i), and
a stop timing of the pulse of the electric bias in (ii) to be later than the stop timing of the pulse of the source high-frequency power.
